(19) United States
(12) Patent Application Publication
(10) Pub. No.: US 2026/0334065 A1
(43) Pub. Date: Oct. 22, 2026

(54) DISPLAY PANEL AND DISPLAY DEVICE

(71) Applicant: HKC CORPORATION LIMITED, Shenzhen (CN)

(72) Inventors: YAO LI, Shenzhen (CN); Lidan Yi, Shenzhen (CN)

(21) Appl. No.: 19/467,818

(22) Filed: Feb. 3, 2026

(30) Foreign Application Priority Data
Feb. 7, 2025 (CN) 202510137928.2

(51) Int. Cl. H10K 59/80; H10K 59/122; H10K 59/38

(52) U.S. Cl. CPC H10K 59/8792; H10K 59/122; H10K 59/38

(57) ABSTRACT

Disclosed in the present disclosure is a display panel and a display device. The display panel includes a substrate, a pixel-defining layer, a plurality of light-emitting elements, a plurality of overhanging structures, a plurality of anti-peeping light sources, a light-shielding layer and an encapsulation layer. The pixel-defining layer is forming a plurality of opening areas. The plurality of light-emitting elements are located in the plurality of opening areas respectively. The plurality of overhanging structures are disposed on the pixel-defining layer and located in a non-opening area. The plurality of anti-peeping light sources are disposed on the plurality of overhanging structures and located in the non-opening area. The light-shielding layer is disposed on the plurality of anti-peeping light sources and located in the non-opening area. The encapsulation layer is disposed on the light-shielding layer and configured to seal the plurality of light-emitting elements.

### CROSS-REFERENCE TO RELATED APPLICATIONS

The present disclosure claims the priority and benefit of Chinese patent application number 2025101379282, titled "Display Panel and Display Device" and filed on Feb. 7, 2025 with China National Intellectual Property Administration, the entire contents of which are incorporated herein by reference.

### TECHNICAL FIELD

The present disclosure relates to the technical field of display, and more particularly relates to a display panel and a display device.

### BACKGROUND

The description provided in this section is intended for the mere purpose of providing background information related to the present disclosure but doesn’t necessarily constitute prior art.

At present, Organic Light Emitting Diode (hereinafter referred to as OLED) display technology has gradually matured, and as a self-emitting display technology, the OLED display technology is being applied more and more widely in products. With the increasing emphasis on personal privacy in modern society, the anti-peeping function of the display panel has also become an essential function of products. Therefore, the OLED anti-peeping technology has also become a hot topic of discussion recently.

Traditional anti-peeping display involves attaching an anti-peeping film to the surface of the display panel. The anti-peeping film generally adopts the ultra fine venetian blind technology. The anti-peeping film principle is similar to that of vertical blinds, which restricts the light from being emitted from the display panel at a fixed angle for display. This is the simplest and most direct solution, with a relatively high yield rate and the most extensive application. However, the conventional anti-peeping film offers limited viewing angle restrictions and anti-peeping effectiveness, and variable adjustment may not be achieved. At the same time, the anti-peeping film also causes a significant loss of light efficiency and an increase in power consumption. Therefore, in the technology to integrate an anti-peeping function to the display panel, the key therefor lies in how to avoid light efficiency loss without affecting the organic light-emitting layer.

### SUMMARY

An objective of the present disclosure is to provide a display panel and a display device. By controlling the on or off state of the plurality of anti-peeping light sources, switching between an anti-peeping function and a normal display function of the display panel may be achieved.

Disclosed in the present disclosure is a display panel, including a substrate, a pixel-defining layer, a plurality of light-emitting elements, a plurality of overhanging structures, a plurality of anti-peeping light sources, a light-shielding layer and an encapsulation layer. The pixel-defining layer is disposed on the substrate and forming a plurality of opening areas. The plurality of light-emitting elements are disposed on the substrate and located in the plurality of opening areas respectively. The plurality of overhanging structures are disposed on the pixel-defining layer and located in a non-opening area, configured to separate every two adjacent light-emitting elements. The plurality of anti-peeping light sources are disposed on the plurality of overhanging structures and located in the non-opening area. The light-shielding layer is disposed on the plurality of anti-peeping light sources and located in the non-opening area, configured to shield vertical outgoing light rays of the plurality of anti-peeping light sources. The encapsulation layer is disposed on the light-shielding layer and configured to seal the plurality of light-emitting elements.

The present disclosure further discloses a display device, the display device includes a display panel and a driving circuit configured to drive the display panel to display, and the display panel includes a substrate, a pixel-defining layer, a plurality of light-emitting elements, a plurality of overhanging structures, a plurality of anti-peeping light sources, a light-shielding layer and an encapsulation layer. The pixel-defining layer is disposed on the substrate and forming a plurality of opening areas. The plurality of light-emitting elements are disposed on the substrate and located in the plurality of opening areas respectively. The plurality of overhanging structures are disposed on the pixel-defining layer and located in a non-opening area, configured to separate every two adjacent light-emitting elements. The plurality of anti-peeping light sources are disposed on the plurality of overhanging structures and located in the non-opening area. The light-shielding layer is disposed on the plurality of anti-peeping light sources and located in the non-opening area, configured to shield vertical outgoing light rays of the plurality of anti-peeping light sources. The encapsulation layer is disposed on the light-shielding layer and configured to seal the plurality of light-emitting elements.

In the present disclosure, by setting a plurality of anti-peeping light sources on the overhanging structure in the non-opening area, the position of the overhanging structure in the non-opening area is utilized to form the plurality of anti-peeping light sources. When the plurality of anti-peeping light sources emits light, the light rays emitted perpendicularly to the substrate by the plurality of anti-peeping light sources are blocked by the light-shielding layer, preventing this part of the light from affecting normal display. However, there are some light rays with an angle or a large angle that are emitted from the opening area. When viewing the display panel from the side, due to the effect of the large angle light rays of the plurality of anti-peeping light sources, the brightness at a large angle is enhanced and the grayscale increases, this results in inaccurate grayscale display at large viewing angles or side viewing angles, or color mixing of multiple sub-pixels that causes halos. Consequently, it leads to color aberration in the display, making it impossible to clearly see the actually displayed image, and fails to achieve anti-peeping for large viewing angles or side viewing angle. When the plurality of anti-peeping light sources is turned on, due to the function of the light-shielding layer, there is no loss in the display image when viewed from the normal viewing angle. Furthermore, by controlling the on or off state of the plurality of anti-peeping light sources, switching between the anti-peeping function and the normal display function of the display panel may be achieved.

### BRIEF DESCRIPTION OF DRAWINGS

The included drawings are provided for further understanding of embodiments of the present disclosure, constitute a part of the specification, illustrate embodiments of the present disclosure, and together with the text description, explain principles of the present disclosure. Obviously, the drawings in the following description are merely some embodiments of the present disclosure. For those of ordinary skill in the art, other drawings may be obtained based on these drawings without creative labor. In the drawings:

FIG. 1 is a schematic diagram of the display panel according to a first embodiment of the present disclosure.

FIG. 2 is a schematic diagram in a top view of the overhanging structure according to the first embodiment of the present disclosure.

FIG. 3 is another schematic diagram of the display panel according to the first embodiment of the present disclosure.

FIG. 4 is a schematic diagram of the display panel according to a second embodiment of the present disclosure.

FIG. 5 is a schematic diagram in a top view of the display panel according to the second embodiment of the present disclosure.

FIG. 6 is a schematic diagram of the display panel according to a third embodiment of the present disclosure.

FIG. 7 is a schematic diagram of the display panel according to a fourth embodiment of the present disclosure.

FIG. 8 is a schematic diagram of another display panel according to the fourth embodiment of the present disclosure.

FIG. 9 is a schematic diagram of a display device of the present disclosure.

### DETAILED DESCRIPTION OF EMBODIMENTS

It should be understood that the terminology, specific structures, and functional details disclosed herein are merely used to describe specific embodiments and are illustrative. However, the present disclosure may be implemented through many alternative forms and should not be construed as limited solely to the embodiments described herein.

In the description of the present disclosure, terms such as "first" and "second" are used solely for descriptive purposes and should not be interpreted as indicating relative importance or implicitly specifying the number of technical features indicated. Thus, unless otherwise specified, features qualified by "first" or "second" may explicitly or implicitly include one or more such features. "A plurality of" means two or more. Additionally, directional or positional terms such as "upper," "lower," "left," "right," "vertical," or "horizontal" are described based on orientations or relative positional relationships shown in the accompanying drawings, which are used for simplified description to facilitate understanding of the present disclosure and do not imply that the devices or elements described should have specific orientations or be constructed or operated in specific orientations. These terms should not be construed as limiting the present disclosure. For those skilled in the art, the specific meaning of the above terms in the context of the present disclosure may be understood according to the specific situation.

The present disclosure is described in detail below with reference to the accompanying drawings and some optional embodiments.

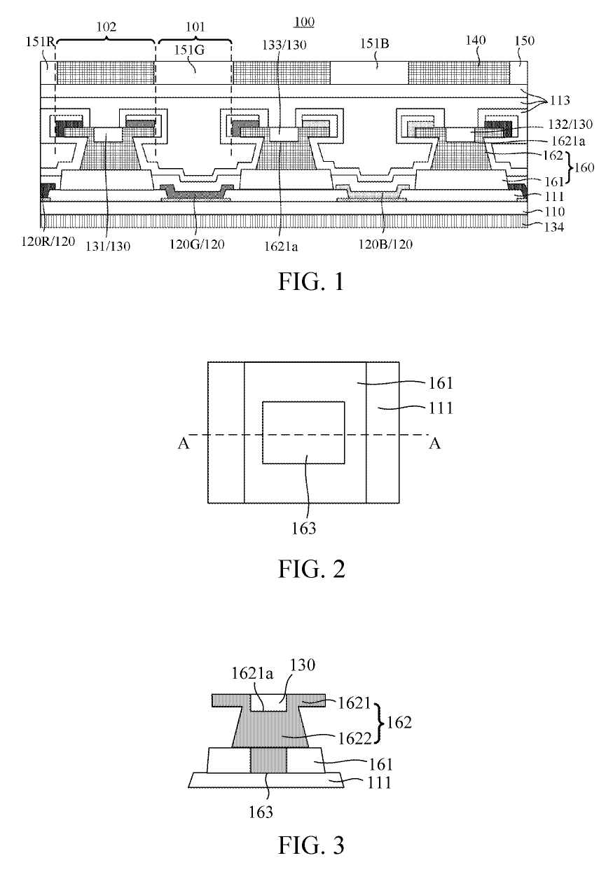

FIG. 1 is a schematic diagram of the display panel according to the first embodiment of the present disclosure. FIG. 2 is a schematic diagram in a top view of the overhanging structure according to the first embodiment of the present disclosure. As shown in FIGS. 1 and 2, the present disclosure discloses a display panel. The display panel includes a substrate 110, a pixel-defining layer 111, a plurality of light-emitting elements 120, a plurality of overhanging structures 160, a plurality of anti-peeping light sources 130, a light-shielding layer 140 and an encapsulation layer 113. The pixel-defining layer 111 is disposed on the substrate 110 and forms a plurality of opening areas 101. The plurality of light-emitting elements 120 are disposed on the substrate 110 and respectively located in the plurality of opening areas 101. The plurality of overhanging structures 160 are disposed on the pixel-defining layer 111 and located in a non-opening area 102, configured to separate every two adjacent light-emitting elements 120. The plurality of anti-peeping light sources 130 are disposed on the plurality of overhanging structures 160 and located in the non-opening area 102. The light-shielding layer 140 is disposed on the plurality of anti-peeping light sources 130 and located in the non-opening area 102, configured to shield vertical outgoing light rays of the plurality of anti-peeping light sources 130. The encapsulation layer 113 is disposed on the light-shielding layer 140 and configured to seal the plurality of light-emitting elements 120.

In the present disclosure, the plurality of anti-peeping light sources 130 is formed by setting it on the overhanging structure 160 in the non-opening area 102, making use of the position of the overhanging structure 160 in the non-opening area 102. When the plurality of anti-peeping light sources 130 emits light, the light rays emitted perpendicularly to the substrate 110 are blocked by the light-shielding layer 140 to prevent this part of the light from affecting normal display. However, there are some light rays with an angle or a large angle that are emitted from the plurality of opening areas 101. When viewing the display panel 100 from the side, due to the effect of the large angle light rays of the plurality of anti-peeping light sources 130, the brightness at a large angle is enhanced and the grayscale increases. This causes inaccurate grayscale display at large viewing angles or side viewing angles, or color mixing of multiple sub-pixels that results in halos, which in turn leads to color aberration in the display, making it impossible to clearly see the actual displayed image, thus achieving anti-peeping for large viewing angles or side viewing angles. When the plurality of anti-peeping light sources 130 is turned on, due to the function of the light-shielding layer 140, there is no loss in the display image when viewed from the normal viewing angle. Furthermore, by controlling the on or off state of the plurality of anti-peeping light sources 130, switching between the anti-peeping function and the normal display function of the display panel 100 may be achieved.

Specifically, the overhanging structure 160 is a key structure in the mask less evaporation technology. In the mask less evaporation technology, by introducing the overhanging structure 160, metal masks are no longer used in device fabrication. Instead, the overhanging structure 160 is configured to separate the light-emitting elements 120 devices between pixels, thus realizing independent light-emitting elements 120. Through the use of the mask less evaporation technology, passive matrix OLED has high resolution and high color, which may better solve the problems of low resolution cathode templates and low yield of light-emitting elements 120 devices. Generally, the overhanging structure 160 needs to have the function of separating film layers. That is, during the evaporation of a certain film layer of the light-emitting elements 120, the overhanging structure 160 may separate the materials of the light-emitting elements 120 in the opening areas 101 from those in the non-opening area 102. The materials of the light-emitting elements 120 in the non-opening area 102 are generally redundant materials and may be removed through subsequent photolithography processes. In this process, without using a metal mask, independent and separated light-emitting elements 120 may be formed in multiple opening areas 101.

In the present disclosure, the plurality of anti-peeping light sources 130 adopts a technology of a metal organic framework (hereinafter referred to as MOFs) material that emits visible light under non-visible light excitation. The MOFs are used as the plurality of anti-peeping light sources 130 by emitting light. The MOFs are a porous material self-assembled from metal ions and organic ligands. Both metal ions and organic ligands may serve as potential luminescent centers, and the pores of MOFs may also load luminescent guests. The MOFs in the present embodiment may emit monochromatic light or polychromatic light. Under the excitation of non-visible light, the colors of the light emitted by adding different organic ligands or metal ions are also different.

For example, lanthanide metal ions (e.g., Ln³⁺, Eu³⁺, Tb³⁺, and Dy³⁺) and organic ligands with non-uniformly distributed carboxyl groups (e.g., isophthalic acid derivatives) first assemble into belt-like structures through anisotropic growth of the metal ions and organic ligands. These nanobands then entwine and undergo gelation to form a MOF gel. Full-color emission from a mixed-metal MOF gel may be prepared by adjusting the type and/or proportion of Ln³⁺ ions. The coordination center lanthanide metal ions (Eu³⁺, Tb³⁺, or Dy³⁺) may produce emissions of different colors, thereby enabling controllable multicolor output under excitation at the same wavelength. Simultaneously, by varying the types and proportions of ions, emission of the same color at different excitation wavelengths may be achieved.

In the present embodiment, the metal-organic framework material is primarily a lanthanide metal organic framework material. The lanthanide metal-organic framework materials possess the characteristic of emitting light under non-visible light excitation and may luminesce in various forms. These include, for example, simultaneous luminescence from both the ligand and the metal ions, simultaneous luminescence from both the host and the guest, simultaneous luminescence from mixed metals, and simultaneous luminescence from mixed MOFs. Taking simultaneous luminescence from the ligand and metal ions as an example, the lanthanide metal ions within the lanthanide organic framework material exhibit the antenna effect. This entails the ligand absorbing energy to reach an excited state, followed by intersystem crossing to the triplet state. The triplet state then sensitizes the lanthanide ions, achieving luminescence via the antenna effect. To achieve simultaneous luminescence from the ligand and metal ions, the energy transfer efficiency from the ligand to the europium ions may be modulated by introducing boronic acid groups onto terephthalic acid. Utilizing simultaneous luminescence from the ligand and metal ions, and leveraging the strong affinity of boronic acid groups towards fluoride ions and H₂O₂, ratiometric luminescent sensing and visual detection of fluoride ions and H₂O₂ are achieved. Differing from modulating energy transfer, aggregation-induced emission ligands and lanthanide ions are configured to prepare MOFs. These MOFs enhance luminescence by restricting the intramolecular rotation of the ligand via coordination. Combining this with the antenna effect luminescence of europium ions enables the simultaneous enhanced luminescence of both the ligand and the europium ions. For example, by adjusting the proportion of lanthanide ions and ligands, taking Ln-MOF[TbₓEu₁₋ₓ(TCBA)(H₂O)]₂·DMF as an example, Eu(III) is characterized by emitting red light, Tb(III) is characterized by emitting green light, and Gd(III) is characterized by emitting blue light. By adjusting the proportions of Eu(III), Tb(III), and Gd(III), changes in luminescence color may be achieved. That is, by combining different ligands with metal ions, MOFs emitting different colors of light may be realized. Whereas for simultaneous host-guest luminescence, mixed metal luminescence, and mixed MOFs luminescence, the employed ligands and metal ions typically differ. Taking simultaneous host-guest luminescence as an example with Ru@MIL-NH₂ material: Ru(bpy)₃ ²⁺exhibits red fluorescence, and MIL-NH₂ exhibits blue fluorescence. Under single wavelength excitation at 300 nm, the MOF achieves blue-red host-guest luminescence. Simultaneous mixed metal luminescence may be prepared by utilizing Ln³⁺ ions having similar atomic radii and coordination modes; mixed lanthanide metal MOFs may be easily prepared by adjusting the proportion of Ln³⁺ ions. Simultaneous mixed MOFs luminescence uses Eu³⁺ and Tb³⁺ as metal nodes, utilizing the red, green, and blue luminescence from Eu³⁺, Tb³⁺, and Dy³⁺, reacting with 2,5-dicarboxyphenylboronic acid to prepare red-emitting Eu-MOFs and green-emitting Tb-MOFs respectively. Together with blue-emitting UiO-66-NH₂, trichromatic MOF ink is prepared.

Besides the four aforementioned luminescence paradigms for achieving multi-luminescent lanthanide metal-organic framework materials, mixed ligands as luminescent centers and single ligands exhibiting multi-luminescence may also be configured to prepare multi-luminescent MOFs. Specifically, lanthanide metal-organic framework materials may be made to exhibit different luminescence colors by adjusting the proportions of Eu(III) and Tb(III), Gd(III); the proportions of Eu³⁺, Tb³⁺, and Dy³⁺; and by selecting non-visible light wavelengths between 250 nm and 350 nm. In the present embodiment, the primary utilization involves the lanthanide metal-organic framework material which, under different material ratios, may emit monochromatic light such as red, green, or blue, thereby achieving red light anti-peeping, green light anti-peeping, and blue light anti-peeping.

Specifically, the display panel 100 of the present disclosure further includes a non-visible light emitter 134. The non-visible light emitter 134 is configured to emit non-visible light towards the anti-peeping light sources 130. In the present embodiment, the non-visible light emitter 134 may be located on the back of the substrate 110 or between the pixel-defining layer 111 and the substrate 110. The non-visible light emitter 134 is controlled to operate through an electrical signal. Since, when the anti-peeping light sources 130 are in operation, it is not necessary to control the brightness of the anti-peeping light sources 130, nor is it necessary to control each anti-peeping light sources 130 individually. It is only necessary to control the anti-peeping light sources 130 to emit different colored light such as red, green, or blue when anti-peeping is required, so that the light rays emitted at large viewing angles are color mixed, making it impossible to see clearly. Moreover, in the OLED display panel 100, the light-emitting elements 120 at different positions may all be controlled individually. Therefore, when some pixels do not display, the anti-peeping light sources 130 may emit light, causing these pixels to also appear to be displaying at large viewing angles, thus interfering with the display content at large viewing angles and achieving anti-peeping at large viewing angles.

The advantages of the metal organic framework material of the present disclosure are that it does not require providing a voltage inside the display panel 100 for driving, but needs to be excited by non-visible light to emit light. That is, it is easy to dispose the plurality of anti-peeping light sources 130 in the non-opening area 102, for example, on the pixel-defining layer 111 or other positions. The anti-peeping light sources 130 may be set by occupying a relatively small space. Compared with the solution in the exemplary technology where the non-opening area 102 is modified and an area of one sub-pixel is occupied to set the anti-peeping light sources 130 synchronously, this method does not need to occupy too much area and does not require modifying the non-opening position within the pixel. Due to the area occupied by the light-emitting elements 120 device, when using the light-emitting elements 120 in the non-opening area 102, the position of the opening needs to be squeezed. When originally three sub-pixels form one pixel, at this time, within one pixel, the anti-peeping sub-pixel will also occupy an area, so that four sub-pixels need to be set, resulting in a reduction in the opening area and causing display problems.

Of course, in one embodiment, the non-visible light emitter 134 may be arranged in partitions, so as to separately control the non-visible light emitters 134 in different partitions to emit light, thus achieving partitioned anti-peeping. The specific partitioning method may be designed according to actual needs, such as upper-lower partitioning, left-right partitioning, and middle partitioning setting, etc. By setting different partitions, the function of partitioned anti-peeping may be achieved.

In one embodiment, the overhanging structure 160 includes a conductive portion 161 and an overhanging portion 162. The overhanging portion 162 is disposed on the conductive portion 161. The overhanging portion 162 includes an upper portion 1621 and a lower portion 1622, and the radial width of the lower portion 1622 is less than that of the upper portion 1621. The conductive portion 161 is provided with a through-groove 163. In the orthographic projection on the substrate 110, the through-groove 163 overlaps with the plurality of anti-peeping light sources 130.

In the present embodiment, the plurality of anti-peeping light sources 130 needs to operate under non-visible light excitation. In the overhanging structure 160, the conductive portion 161 is generally formed of an opaque metal material, which results in the non-visible light being unable to pass through the conductive portion 161 and reach the plurality of anti-peeping light sources 130, thus making it impossible to excite the plurality of anti-peeping light sources 130 to emit light normally. Therefore, in the present solution, by making use of the region where the overhanging structure 160 is located, the through-groove 163 is provided on the conductive portion 161. Generally, only the lanthanide metal organic framework material in the region of the through groove 163 may emit visible light, thereby achieving the anti-peeping function.

Generally, the lanthanide metal organic framework material may be formed on the overhanging structure 160 by printing or coating. Certainly, this lanthanide metal organic framework material may also be part of the overhanging structure 160, thus replacing the overhanging portion 162 of the overhanging structure 160. The present embodiment includes ways such as setting a groove 1621a on the overhanging portion 162 to accommodate the anti-peeping light sources 130 and replacing the overhanging portion 162 with the material of the plurality of anti-peeping light sources 130, but is not limited to these ways.

Specifically, the present embodiment relates to a new technology in which a COE (Color film on Encapsulation, forming a color filter on a thin film encapsulation structure) replaces a polarizer. That is, a color filter layer 150 is provided on the encapsulation layer 113. The color filter layer 150 has multiple color filter portions respectively set in a plurality of opening areas 101. Generally, the color filter portions include a red filter portion 151R, a green filter portion 151G, and a blue filter portion 151B. Three adjacent color filter portions of different colors may constitute a pixel, which may be respectively called a red sub-pixel, a green sub-pixel, and a blue sub-pixel. By controlling the light brightness of the red filter portion 151R, the light brightness of the green filter portion 151G, and the light brightness of the blue filter portion 151B, any color may be formed within one pixel. That is, by controlling the grayscale of the red sub-pixel, the grayscale of the green sub-pixel, and the grayscale of the blue sub-pixel, the display of different colors may be achieved. In the organic light-emitting display panel 100, different colors are mainly displayed by controlling the brightness of the light-emitting elements 120.

Specifically, the color filter layer 150 is disposed on the encapsulation layer 113. The color filter layer 150 includes a plurality of color filter portions. The plurality of color filter portions are located in the opening area 101. The light-shielding layer 140 is disposed on the same layer as the color filter portions. The light-shielding layer 140 is disposed on the anti-peeping light source 130 and is located in the non-opening area 102, and is configured to shield vertical outgoing light rays of the anti-peeping light source 130.

In the present embodiment, the light-shielding layer 140 that blocks the vertically emitted light rays of the plurality of anti-peeping light sources 130 is disposed on the same layer as the color filter portions. That is, the black matrix in the color filter layer 150 is utilized to achieve the light-shielding effect for the plurality of anti-peeping light sources 130, preventing the plurality of anti-peeping light sources 130 from affecting the front view. The color filter portions also have the function of absorbing and filtering ambient light. Generally, the color filter portions include a red filter portion 151R, a green filter portion 151G, and a blue filter portion 151B. The red filter portion 151R may absorb light rays of other colors and transmit red light rays. The green filter portion 151G may absorb light rays of other colors and transmit green light rays. The blue filter portion 151B may absorb light rays of other colors and transmit blue light rays.

Specifically, the red filter portion 151R and the red light-emitting element 120R are set within the same opening area 101. The green filter portion 151G and the green light-emitting element 120G are set within the same opening area 101. The blue filter portion 151B and the blue light-emitting element 120B are set within the same opening area 101. At least one adjacent red light-emitting element 120R, one green light-emitting element 120G, and one blue light-emitting element 120B constitute a pixel. Within one pixel, at least one anti-peeping light source 130 is set. The plurality of anti-peeping light sources 130 is set between the red light-emitting element 120R and the blue light-emitting element 120B, between the red light-emitting element 120R and the green light-emitting element 120G, or between the green light-emitting element 120G and the red light-emitting element 120R. Specifically, in the present embodiment, at least one anti-peeping light source 130 is set within one pixel. By using this anti-peeping light sources 130, color mixing anomalies may occur when the pixel is displayed at a large viewing angle, resulting in an unclear view at large angles.

In the present embodiment, due to the monochromatic light filtering effect of the color filter portions, when the plurality of anti-peeping light sources 130 emits monochromatic light, although it may match the color filter portion of the same color, it may not pass through the adjacent color filter portions of other colors. Taking the case where the anti-peeping light sources 130 emit red light rays as an example, these red light rays may pass through the red filter portion 151R for emission, while the red light rays at the positions of the green filter portion 151G and the blue filter portion 151B are absorbed and may not be emitted. At this time, at large angles, there is an abnormal brightness of the red sub-pixel, making it impossible to clearly see the display content at large viewing angles or side viewing angles, thus achieving anti-peeping.

However, relatively speaking, since the red emitted light rays will be absorbed by the green filter portion 151G and the blue filter portion 151B, the light utilization rate of the anti-peeping light sources 130 is relatively low, resulting in a need for higher power consumption to achieve a better anti-peeping effect. Therefore, the anti-peeping light sources 130 may also adopt a two-color or multi-color light-emitting method. The visible light emitted by the anti-peeping light sources 130 includes two or more of blue light rays, green light rays, or red light rays.

Continuing to refer to FIG. 1, in the present embodiment, the anti-peeping light sources 130 adopt a two-color light-emitting mode. The anti-peeping light sources 130 may be divided into a first color anti-peeping portion 131, a second color anti-peeping portion 132, and a third color anti-peeping portion 133. That is, the anti-peeping light sources 130 includes a first color anti-peeping portion 131, a second color anti-peeping portion 132, and a third color anti-peeping portion 133. The first color anti-peeping portion 131 is set between the red light-emitting element 120R and the green light-emitting element 120G. The second color anti-peeping portion 132 is set between the red light-emitting element 120R and the blue light-emitting element 120B. The third color anti-peeping portion 133 is set between the green light-emitting element 120G and the blue light-emitting element 120B. The first color anti-peeping portion 131 is configured to emit red light rays and green light rays under non-visible light excitation. The second color anti-peeping portion 132 is configured to emit red light rays and blue light rays under non-visible light excitation. The third color anti-peeping portion 133 is configured to emit green light rays and blue light rays under non-visible light excitation.

In the present embodiment, by controlling the anti-peeping light sources 130 to emit two color light rays, the light rays emitted by the anti-peeping light sources 130 set between two color filter portions may be emitted respectively through the two color filter portions. Thus, the emitted light rays of the anti-peeping light sources 130 are fully utilized for anti-peeping. Moreover, the anti-peeping light sources 130 may only emit two color light rays, without interference from light rays of other colors. Importantly, this enables the display panel 100 to have anti-peeping functions at the four side viewing angles (left, right, up and down). In contrast, a monochromatic anti-peeping light source 130 is likely to have a situation where it may achieve anti-peeping at one side viewing angle but may fail to do so at other side viewing angles.

Certainly, in the present embodiment, the ligands and metal ions of the lanthanide metal organic framework material may also be controlled, thereby controlling the anti-peeping light sources 130 to emit red, green, and blue light rays. During display, various colors of display light rays may be obtained by the mutual superposition of light-emitting elements 120 of different colors and color filter portions. Similarly, various colors of anti-peeping light rays may be obtained by the mutual superposition of anti-peeping light sources 130 of different colors to achieve a better anti-peeping effect. It may be understood that since the light-emitting elements 120 of the OLED display panel 100 may all be controlled individually, when some pixel positions do not display, the first color anti-peeping portion 131, the second color anti-peeping portion 132, and the third color anti-peeping portion 133 are made to work at this time. This makes the non-displaying pixels at large viewing angles also display, thus further making the display content at large viewing angles unreadable.

It is worth mentioning that the solution of the present disclosure may also be employed for OLED display panels without the COE technology. Correspondingly, the black matrix in the color filter layer may not be utilized for the light-shielding layer. Instead, an additional light-shielding layer needs to be formed on the anti-peeping light source to block the vertically emitted light rays of the anti-peeping light source.

FIG. 3 is another schematic diagram of the display panel according to the first embodiment of the present disclosure. As shown in FIG. 3, FIG. 3 is a cross sectional schematic view after cutting along the cutting line AA in FIG. 2. In the present embodiment, the anti-peeping light sources 130 may be accommodated by setting a groove 1621a on the overhanging portion 162 of the overhanging structure 160.

Specifically, the upper portion 1621 is provided with a plurality of grooves 1621a. The anti-peeping light sources 130 are respectively disposed in the grooves 1621a. The positions of the grooves 1621a correspond one by one to those of the above mentioned through-grooves 163, so that the anti-peeping light sources 130 may receive the non-visible light passing through the through-grooves 163. Since the grooves 1621a need to be formed, a semi-mask technique is adopted to form the grooves 1621a for accommodating the anti-peeping light sources 130 when forming the upper portion 1621 of the overhanging portion 162.

In the present embodiment, by setting grooves 1621a on the upper portion 1621 of the overhanging portion 162 to accommodate the anti-peeping light sources 130, the non-opening area 102 is enabled to have the ability to emit large angle light rays. Moreover, there is no interaction between the lanthanide metal organic framework material and the material of the upper portion 1621. The anti-peeping light sources 130 are set in the grooves 1621a of the upper portion 1621, and during subsequent encapsulation processes, the anti-peeping light sources 130 are sealed in the grooves 1621a by the encapsulation layer 113. Certainly, considering that the thickness of the upper portion 1621 of the overhanging portion 162 is relatively thin when the upper portion 1621 is formed of an inorganic insulating material. In this case, the anti-peeping light sources 130 may be directly disposed on the upper portion 1621 of the overhanging portion 162, and the encapsulation layer 113 covers the anti-peeping light sources 130 through subsequent encapsulation.

It may be understood that in the case where the through-groove 163 is formed in the conductive portion 161, since the through-groove 163 needs to be filled by the overhanging portion 162, that is, a groove 1621a is formed on the upper portion 1621, and the groove 1621a may be configured to accommodate the anti-peeping light sources 130. In the non-opening area 102 of the display panel 100, a light-shielding layer 140 is generally also provided. The main function of the light-shielding layer 140 is to prevent external light from entering and causing problems such as reflection. In the present embodiment, a light-shielding layer 140 is provided above the anti-peeping light sources 130. The light-shielding layer 140 has a certain gap from the anti-peeping light sources 130, so that the vertically emitted light rays of the anti-peeping light sources 130 are blocked by the light-shielding layer 140, while the obliquely emitted light rays may be emitted from the adjacent opening area 101, thus achieving anti-peeping. In subsequent embodiments, the light-shielding layer 140 is also set in the same way, which is not elaborated here again.

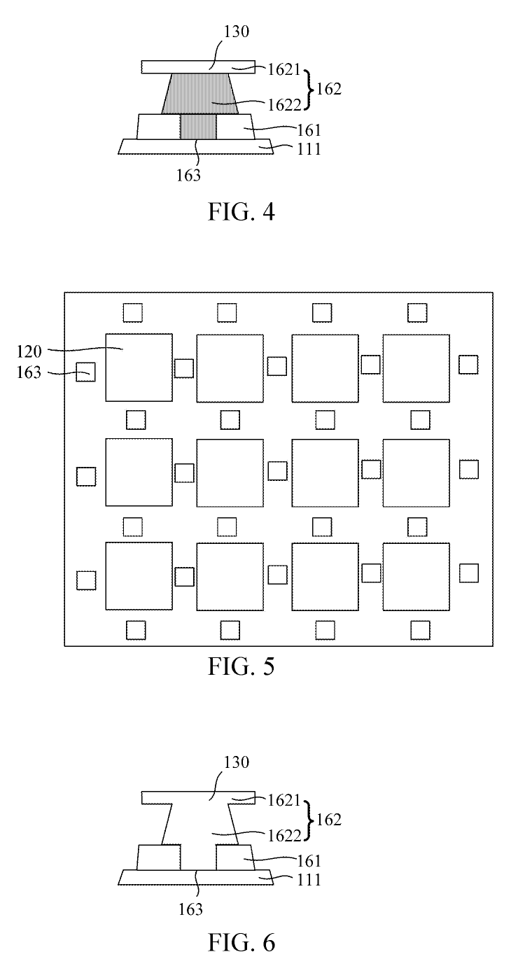

FIG. 4 is a schematic diagram of the display panel according to a second embodiment of the present disclosure. As shown in FIG. 4, in the present embodiment, by replacing the material of the upper portion 1621 of the overhanging portion 162, the lanthanide metal organic framework material is configured to replace the material of the upper portion 1621 to form the upper portion 1621 of the overhanging portion 162.

Specifically, the upper portion 1621 is formed of the lanthanide metal organic framework material to serve as the anti-peeping light sources 130.

In the present embodiment, when forming the overhanging structure 160 of the display panel 100, first, the conductive portion 161 of the overhanging structure 160 is formed. Then, a through-groove 163 is formed in the conductive portion 161. Next, the lower portion 1622 of the overhanging portion 162 is formed. Finally, the upper portion 1621 of the overhanging portion 162 is formed using the lanthanide metal organic framework material. After forming the pattern of the upper portion 1621 of the metal organic framework material, the lower portion 1622 is etched using the photoresist protective layer above. The material of the lower portion 1622 of the overhanging portion 162 is generally formed of an insulating material, thereby forming the overhanging portion 162 with the radial width of the upper portion 1621 being greater than that of the lower portion 1622.

Since the projection of the overhanging structure 160 on the substrate 110 is a criss-cross reticular structure, each opening area 101 corresponds to a mesh hole in the reticular structure. That is, the overhanging structure 160 is disposed around each of the light-emitting elements 120. The overhanging structure 160 is disposed surrounding each light-emitting element 120, and two adjacent light-emitting elements 120 share one overhanging structure 160.

FIG. 5 is a schematic diagram in a top view of the display panel according to the second embodiment of the present disclosure. As shown in FIG. 5, by replacing the upper portion 1621 of the overhanging portion 162 with the material of the anti-peeping light sources 130, during the formation process, the lanthanide metal organic framework material may be formed into a reticular upper portion 1621 by printing or coating. Compared with the anti-peeping light sources 130 formed at the positions of multiple through-grooves 163 in the previous embodiment, this reduces the manufacturing process complexity. Moreover, the characteristics of the metal organic framework material may also serve as the upper portion 1621 of the overhanging portion 162, achieving the function of the overhanging structure 160 to isolate the light-emitting elements 120. In the present embodiment, the upper portion 1621 of the overhanging portion 162 may be completely replaced by the lanthanide metal organic framework material, and the metal organic framework material in the region of the through-groove 163 may emit light under non-visible light excitation.

In one embodiment, considering that the overhanging structure 160 needs to isolate adjacent light-emitting elements 120 during the manufacturing process of the light-emitting elements 120, and when depositing each film layer in the light-emitting elements 120, various material particles need to be emitted from the evaporation source. In order to prevent these material particles from entering the porous gaps of the lanthanide metal organic framework material, the width of the porous gaps of the lanthanide metal organic framework material may be set to be less than the width of the particles emitted from the evaporation source. Certainly, a protective layer may also be set on the lanthanide metal organic framework material to prevent the particles emitted from the evaporation source from entering the porous structure of the lanthanide metal organic framework material.

FIG. 6 is a schematic diagram of the display panel according to a third embodiment of the present disclosure. As shown in FIG. 6, in the present embodiment, the material of the overhanging portion 162 may also be replaced, and the lanthanide metal organic framework material may be configured to form the overhanging portion 162.

Specifically, the upper portion 1621 and the lower portion 1622 are respectively formed of the lanthanide metal organic framework material to serve as the anti-peeping light sources 130.

In the present embodiment, the upper portion 1621 and the lower portion 1622 of the overhanging portion 162 are respectively replaced with the lanthanide metal organic framework material, instead of being formed of an insulating material. The advantage is that the lanthanide metal organic framework material may be directly formed by coating and printing, without using methods such as deposition and etching, and the overhanging portion 162 may be directly formed on the conductive portion 161.

Specifically, the angle formed between the bottom surface of the upper portion 1621 and the side surface of the lower portion 1622 is in a range from 40 degrees to 80 degrees.

In the present embodiment, due to the better strength and toughness of the metal organic framework material, when forming the overhanging portion 162, the angle formed between the bottom surface of the upper portion 1621 and the side surface of the lower portion 1622 may be made larger. For the overhanging portion 162 formed of an insulating material, such as an inorganic insulating material in the above mentioned embodiment, due to the limitations of the strength and toughness of the inorganic insulating material, the maximum included angle between the bottom surface of the upper portion 1621 and the side surface of the lower portion 1622 is 60 degrees, generally between 45 degrees and 60 degrees. However, the angle formed between the bottom surface of the upper portion 1621 and the side surface of the lower portion 1622 may reach a maximum of 80 degrees by using the metal organic framework material. The larger the angle, the smaller the space occupied by the overhanging structure 160, and the better the isolation effect of the overhanging structure 160 on the light-emitting elements 120. The area of the opening area 101 may be increased by reducing the size of the overhanging structure 160 itself.

Certainly, in another embodiment, the anti-peeping light sources 130 may also be set at the positions of the upper portion 1621 and the lower portion 1622 of the overhanging portion 162 corresponding to the through-groove 163. In this way, the upper portion 1621 and the lower portion 1622 formed of the insulating material do not need to be completely replaced, but only the upper portion 1621 and the lower portion 1622 formed of the insulating material in the region of the through groove 163 are replaced.

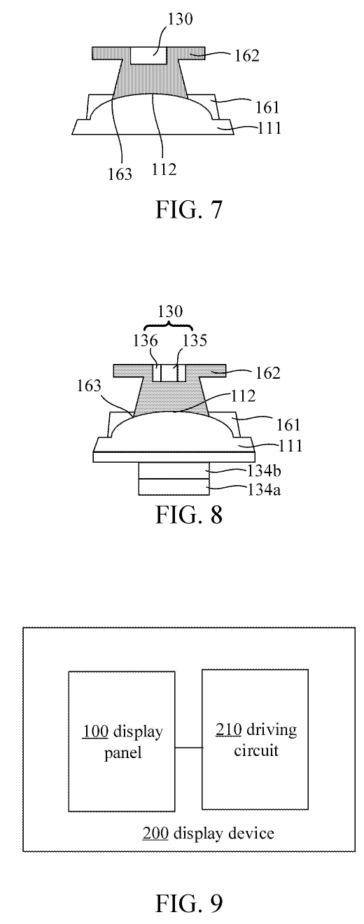

FIG. 7 is a schematic diagram of the display panel according to a fourth embodiment of the present disclosure. As shown in FIG. 7, at the position of the through-groove 163, a convex surface 112 is provided on a side of the pixel-defining layer close to the overhanging structure 160. The convex surface 112 is configured to diverge the non-visible light onto the anti-peeping light sources 130.

The main function of this convex surface 112 is to diverge the non-visible light. Since the conductive portion 161 of the overhanging structure 160 is also a reticular structure, the conductive portion 161 between adjacent light-emitting elements 120 needs to conduct electricity continuously. Therefore, when setting the through-groove 163, without disconnecting the conductive portion 161, the width of the through-groove 163 set on the conductive portion 161 is relatively small. That is, the through-groove 163 is surrounded by the conductive portion 161 on each side, so as to achieve the connection of the conductive portion 161. Thus, in the present embodiment, after the non-visible light is diverged by the convex surface 112, it is emitted onto the anti-peeping light sources 130 on the overhanging portion 162, causing the anti-peeping light sources 130 with a larger area to emit light, thereby enhancing the anti-peeping effect.

Among them, the convex surface 112 may mainly be formed by adjusting the etched pattern, so that the pixel-defining layer 111 has a certain curved surface and protrudes in the direction of the overhanging structure 160, thus playing the role of diverging and homogenizing the non-visible light.

FIG. 8 is a schematic diagram of another display panel according to the fourth embodiment of the present disclosure. As shown in FIG. 8, the anti-peeping light sources 130 includes at least a first anti-peeping portion 135 and a second anti-peeping portion 136. The non-visible light emitter 134 includes at least a first excitation layer 134a and a second excitation layer 134b. The first anti-peeping portion 135 is configured to emit the first anti-peeping light rays under the control of the first excitation layer 134a, and the second anti-peeping portion 136 is configured to emit the second anti-peeping light rays under the control of the second excitation layer 134b. A wavelength range of the non-visible light emitted by the first excitation layer 134a is different from that of the second excitation layer 134b.

Among them, the intensity of the first anti-peeping light rays is less than that of the second anti-peeping light rays. The present disclosure is adapted to anti-peeping in different modes. For example, the first anti-peeping light rays are employed for anti-peeping when the display is at a low brightness, and the second anti-peeping light rays are employed for anti-peeping when the display is at a high brightness.

In the present embodiment, two anti-peeping portions are taken as an example for illustration. In practice, the number of anti-peeping portions is not limited to two and needs to be designed according to the actual situation. In this solution, it is mainly considered that in high brightness and low brightness displays, if the brightness of the anti-peeping light rays for the two displays is the same, display problems such as light leakage may occur, especially in low brightness displays. When the brightness of the anti-peeping light sources 130 is relatively high, light leakage is likely to occur. While in high brightness displays, if the brightness of the anti-peeping light sources 130 is relatively low, it is likely that the anti-peeping effect may not be achieved. Therefore, in the present embodiment, it is necessary to distinguish the anti-peeping of the side viewing angles in high brightness and low brightness displays. For example, in high brightness displays, the brightness of the anti-peeping light rays is greater, and in low brightness displays, the brightness of the anti-peeping light rays is smaller, so as to achieve a better anti-peeping effect.

Specifically, in the present embodiment, mainly due to the different wavelengths emitted by the first excitation layer 134a and the second excitation layer 134b, the first anti-peeping portion 135 and the second anti-peeping portion 136 may be controlled to work separately or simultaneously, achieving at least two-step anti-peeping brightness levels for the first anti-peeping portion 135, the second anti-peeping portion 136 work separately and simultaneously. Certainly, by continuously increasing the number of anti-peeping portions, multi-step brightness compensation may be achieved. For example, the brightness range of the display panel 100 may be divided into a first brightness range and a second brightness range, or more. The first brightness range is a low brightness display range, and the second brightness range is a high brightness display range.

In one embodiment, the brightness of the first anti-peeping portion 135 and the second anti-peeping portion 136 may be the same or different. When the brightness of the first anti-peeping portion 135 and the second anti-peeping portion 136 is the same, it is necessary to control the first anti-peeping portion 135 and the second anti-peeping portion 136 to turn on simultaneously and separately to achieve different compensated brightness levels. When the brightness of the first anti-peeping portion 135 and the second anti-peeping portion 136 is set to be different, by separately controlling the activation or deactivation of the first anti-peeping portion 135 or the second anti-peeping portion 136, anti-peeping may be achieved to adapt to the multi-step brightness of the display panel 100.

In another embodiment, the second anti-peeping portion 136 is arranged surrounding the first anti-peeping portion 135, and the first anti-peeping portion 135 and the second anti-peeping portion 136 are set on the same layer. The anti-peeping light sources 130 mentioned above are located in one through-groove 163. In the present embodiment, due to the different position settings of the second anti-peeping portion 136 and the first anti-peeping portion 135, there are also differences in their large viewing angle perspectives. The second anti-peeping portion 136 arranged on the outside, because it is set near the opening area 101, has a smaller deviation in the emission angle compared to the first anti-peeping portion 135. That is, the side viewing angle anti-peeping angle of the first anti-peeping portion 135 is larger, enabling the user to see the anti-peeping emitted light rays from the first anti-peeping portion 135 at a larger side viewing angle, achieving anti-peeping at a larger angle.

FIG. 9 is a schematic diagram of a display device of the present disclosure. As shown in FIG. 9, the present disclosure also discloses a display device. The display device 200 includes a driving circuit 210 and the display panel 100 in any of the above mentioned embodiments. The driving circuit 210 is configured to drive the display panel 100 to display.

It should be noted that the inventive concept of the present disclosure may be formed into many embodiments, but limitations of the disclosure document preclude exhaustive listing. Therefore, should no conflict be present, the various embodiments or technical features described above may be arbitrarily combined to form new embodiments. After the various embodiments or technical features are combined, the original technical effects may be enhanced.

The foregoing content describes the present disclosure in further detail in conjunction with specific optional embodiments, but it should not be construed that the specific implementation of the present disclosure is limited solely to these descriptions. For those of ordinary skill in the art to which the present disclosure pertains, several simple deductions or replacements may be made without departing from the inventive concept of the present disclosure, and these should all be regarded as falling within the protection scope of the present disclosure.

What is claimed is:

1. A display panel, comprising:
a substrate;
a pixel-defining layer, disposed on the substrate, forming a plurality of opening areas;
a plurality of light-emitting elements, disposed on the substrate, located in the plurality of opening areas respectively;
a plurality of overhanging structures, disposed on the pixel-defining layer, located in a non-opening area, configured to separate every two adjacent light-emitting elements;
a plurality of anti-peeping light sources, disposed on the plurality of overhanging structures, located in the non-opening area;
a light-shielding layer, disposed on the plurality of anti-peeping light sources, located in the non-opening area, configured to shield vertical outgoing light rays of the plurality of anti-peeping light sources; and
an encapsulation layer, disposed on the light-shielding layer, configured to seal the plurality of light-emitting elements.

2. The display panel according to claim 1, wherein each of the plurality of anti-peeping light sources is formed of lanthanide metal organic framework material, each of the plurality of anti-peeping light sources is configured to generate visible light under non-visible light excitation, the visible light comprises at least one of blue light, green light, or red light; and
the display panel further comprises a non-visible light emitter, and the non-visible light emitter is configured to emit the non-visible light toward the plurality of anti-peeping light sources.

3. The display panel according to claim 2, wherein each of the plurality of overhanging structures comprises a conductive portion and an overhanging portion, the overhanging portion is disposed on the conductive portion, the overhanging portion comprises an upper portion and a lower portion, and a radial width of the lower portion is less than that of the upper portion; and
the conductive portion is provided with a through-groove, and the through-groove overlaps with one of the plurality of anti-peeping light sources in an orthographic projection on the substrate.

4. The display panel according to claim 3, wherein the upper portion is provided with a plurality of grooves, and the plurality of anti-peeping light sources are respectively disposed in the plurality of grooves.

5. The display panel according to claim 3, wherein the upper portion is formed of the lanthanide metal organic framework material to serve as each of the plurality of anti-peeping light sources.

6. The display panel according to claim 3, wherein the upper portion and the lower portion are respectively formed of the lanthanide metal organic framework material to serve as each of the plurality of anti-peeping light sources.

7. The display panel according to claim 6, wherein an angle formed between a bottom surface of the upper portion and a side surface of the lower portion is in a range from 40 degrees to 80 degrees.

8. The display panel according to claim 3, wherein the upper portion or the lower portion is formed of the lanthanide metal organic framework material to serve as each of the plurality of anti-peeping light sources at a position of the through-groove.

9. The display panel according to claim 3, wherein a convex surface is disposed on a side of the pixel definition layer close to the overhanging structure at a position of the through-groove, and the convex surface is configured to diverge the non-visible light onto the plurality of anti-peeping light sources.

10. The display panel according to claim 3, wherein each of the plurality of anti-peeping light sources comprises at least a first anti-peeping portion and a second anti-peeping portion, the non-visible light emitter comprises at least a first excitation layer and a second excitation layer, the first anti-peeping portion is configured to emit first anti-peeping light rays under control of the first excitation layer, and the second anti-peeping portion is configured to emit second anti-peeping light rays under control of the second excitation layer, a wavelength range of the non-visible light emitted by the first excitation layer is different from that of the second excitation layer; and
wherein an intensity of the first anti-peeping light rays is less than that of the second anti-peeping light rays.

11. The display panel according to claim 2, wherein the non-visible light emitter is disposed in partitions, configured to independently control the non-visible light emitter in different partitions to emit light.

12. The display panel according to claim 1, wherein the display panel further comprises a color filter layer, the color filter layer comprises a plurality of color filter portions, and the plurality of color filter portions are respectively disposed in the plurality of opening areas.

13. The display panel according to claim 12, wherein the light-shielding layer is disposed on a same layer as the plurality of color filter portions.

14. The display panel according to claim 12, wherein the plurality of color filter portions comprises a red filter portion, a green filter portion and a blue filter portion; the plurality of light-emitting elements comprises a red light-emitting element, a green light-emitting element and a blue light-emitting element;
the red filter portion and the red light-emitting element are disposed in the same one of the plurality of opening areas, the green filter portion and the green light-emitting element are disposed in the same one of the plurality of opening areas, the blue filter portion and the blue light-emitting element are disposed in the same one of the plurality of opening areas; and
at least one adjacent the red light-emitting element, one green light-emitting element and one blue light-emitting element constitute a pixel, at least one of the plurality of anti-peeping light sources is provided in the pixel.

15. The display panel according to claim 14, wherein each of the plurality of anti-peeping light sources comprises a first color anti-peeping portion, a second color anti-peeping portion, and a third color anti-peeping portion, the first color anti-peeping portion is disposed between the red light-emitting element and the green light-emitting element, the second color anti-peeping portion is disposed between the red light-emitting element and the blue light-emitting element, the third color anti-peeping portion is disposed between the green light-emitting element and the blue light-emitting element;
wherein the first color anti-peeping portion is configured to emit a red light and a green light under non-visible light excitation, the second color anti-peeping portion is configured to emit the red light and a blue light under non-visible light excitation, the third color anti-peeping portion is configured to emit the green light and the blue light under non-visible light excitation.

16. A display device, comprising a display panel and a driving circuit configured to drive the display panel to display, and the display panel comprises:
a substrate;
a pixel-defining layer, disposed on the substrate, forming a plurality of opening areas;
a plurality of light-emitting elements, disposed on the substrate, located in the plurality of opening areas respectively;
a plurality of overhanging structures, disposed on the pixel-defining layer, located in a non-opening area, configured to separate every two adjacent light-emitting elements;
a plurality of anti-peeping light sources, disposed on the plurality of overhanging structures, located in the non-opening area;
a light-shielding layer, disposed on the plurality of anti-peeping light sources, and located in the non-opening area, configured to shield vertical outgoing light rays of the plurality of anti-peeping light sources; and
an encapsulation layer, disposed on the light-shielding layer, configured to encapsulate the plurality of light-emitting elements.

17. The display device according to claim 16, wherein each of the plurality of anti-peeping light sources is formed of lanthanide metal organic framework material, each of the plurality of anti-peeping light sources is configured to generate visible light under non-visible light excitation, the visible light comprises at least one of blue light, green light, or red light; and
the display panel further comprises a non-visible light emitter, the non-visible light emitter is configured to emit the non-visible light towards the plurality of anti-peeping light sources.

18. The display device according to claim 17, wherein each of the plurality of overhanging structures comprises a conductive portion and an overhanging portion, the overhanging portion is disposed on the conductive portion, the overhanging portion comprises an upper portion and a lower portion, and a radial width of the lower portion is less than that of the upper portion; and
the conductive portion is provided with a through-groove, and the through-groove overlaps with one of the plurality of anti-peeping light sources in an orthographic projection on the substrate.
